(19) United States
(12) Patent Application Publication
(10) Pub. No.: US 2008/0286978 A1
(43) Pub. Date: Nov. 20, 2008

(54) ETCHING AND PASSIVATING FOR HIGH ASPECT RATIO FEATURES

(76) Inventors: Rong Chen, Sunnyvale, CA (US); Tae Won Kim, San Jose, CA (US); Nicolas Gani, San Jose, CA (US); Anisul H. Khan, Santa Clara, CA (US)

Correspondence Address: APPLIED MATERIALS/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/749,957

(22) Filed: May 17, 2007

(51) Int. Cl. H01L 21/302

(52) U.S. Cl. 438/713; 257/E21.214

(57) ABSTRACT

An etch method includes etching a masked substrate to form a recess with a first sidewall in the substrate. A thin surface layer of the substrate on the first sidewall is then converted into a passivation layer. The masked substrate is etched again to deepen the recess in the substrate. A surface layer of the substrate on the second sidewall of the recess is then converted into a passivation layer. In one embodiment, upon removal of the passivation layers from both sidewalls, the first and second sidewalls of the high aspect ratio recess are aligned to within 10 Å of each other to provide a high aspect ratio recess having a vertical profile.

### BACKGROUND

1. Field

Embodiments of the present invention relate to the electronics manufacturing industry and more particularly to etching and passivating.

2. Discussion of Related Art

As high volume manufacturing of microelectronics reaches the 32 nanometer (nm) technology node, the critical dimension (CD) requirement of all features in the front end of line (FEOL) becomes increasingly demanding. With the 32 nm node there are significantly tighter specifications than the current 45 node. The average half-pitch of a dynamic random access memory (DRAM) manufactured at the 45 nm technology level is expected to be 30-35 nm. The shrink in half-pitch translates into a more demanding aspect ratio (AR) for the DRAM gate recess etch. AR, as used herein, is defined as the minimum width of a recess, such as a via or trench, to the depth of the recess. For example, the critical dimensions (CD) of the recess at the 45 nm node is approximately 40 nm while the recess depth is typically 1500 Å, providing an AR of approximately 3.75:1. At the 32 nm technology node, the gate recess CD is expected to shrink to approximately 30 nm while the gate recess depth is expected to increase to at least 1800 Å. Similarly, at the 22 nm technology node, the gate recess CD is expected to shrink to approximately 21 nm while the gate recess depth is expected to increase to 2000 Å. Thus, the AR of the DRAM gate recess etch is expected to increase to 6:1 at 32 nm and 10:1 at 22 nm.

Unfortunately, conventional polysilicon etch processes employed for the gate recess etch have proven incapable of providing vertical sidewalls with AR greater than about 4:1. These conventional etch processes typically employ a single main etch process with plasma from a gas mixture including hydrogen bromide (HBr), chlorine (Cl₂), sulfur hexafluoride (SF₆), nitrogen (N₂), and oxygen (O₂). The roles of the components in this complex gas mixture are generally understood. The gas mixture gives good etching and passivation balance. The passivation layer is likely to be silicon halogenides (or silicon oxyhalogenides if with O₂ addition). Though this conventional etch condition has evolved over many generations, it provides unsatisfactory sidewall profiles when the AR of the recess becomes greater than 4:1.

Typically, there are two types of unsatisfactory profiles which result from attempting to etch substrate 120 by balancing the plasma conditions in the conventional single-step etch process. The first type is shown in FIG. 1A and the second in FIG. 1B. A classic necked profile 130 with a “strawberry bottom” 135 is shown in FIG. 1A. This profile is generally the result of process conditions resulting in too much passivation. Alternatively, an undercut, bowing profile 140 in substrate 120 is shown in FIG. 1B. Such a profile is generally the result of process condition resulting in too little passivation. Both the profiles depicted in FIG. 1A and FIG. 1B are unsatisfactory because a highly vertical profile is necessary to achieve optimal device density and device performance.

### SUMMARY

An etch method is described herein. The method may be employed to etch a high aspect ratio recess with a vertical profile superior to that achievable with single-step etch methods. The method may further be employed to etch recesses with discontinuous profiles, for example vertical for a portion and then undercut or tapered for a portion. The method includes etching a masked substrate to form recess with a first sidewall in the substrate. A surface layer of the substrate on the first sidewall is then converted into a passivation layer. In one implementation, the surface layer of the substrate on the first sidewall is converted into the passivation layer with a plasma tuned to provide a passivation layer with a thickness less than 50 Å. The masked substrate is then etched again, selectively relative to the passivation layer, to deepen the recess, forming a second sidewall in the substrate and thereby increasing the aspect ratio. In a particular embodiment, a plasma etch deepens the recess anisotropically with a second sidewall in the substrate aligned with the passivation layer on the first sidewall.

In one embodiment, the process conditions of the first etch of the substrate and the second etch of the substrate are substantially the same. In a particular embodiment, a first plasma etch forms a recess with an aspect ratio less than 4:1 and a second plasma etch increases the total aspect ratio of the recess to greater than 4:1. In a further embodiment, the second plasma etch increases the total aspect ratio of the recess to greater than 5:1. In one such implementation, the first plasma etch removes more of the substrate than second plasma etch. However, the passivating and etching processes may be performed repeatedly to iteratively reach a desired final recess depth and profile.

In another embodiment, the passivation layer formed on the first sidewall (prior to the second etch of the substrate) has a thickness no greater than the thickness of a native oxide of the substrate. For example, the surface layer of the substrate on the first sidewall may be converted into a passivation layer less than 50 Å thick. In one such embodiment, a plasma passivation converts the surface layer of the substrate on the first sidewall into an oxide of the substrate. In one implementation, the passivation layer may be formed on the first sidewall by isotropically oxidizing the recess and then anisotropically etching the oxidized substrate layer with a plasma to break through the passivation layer at the bottom of the recess in preparation for deepening the recess with the second etch of the substrate. In particular embodiment, the substrate comprises polycrystalline silicon and a plasma forms passivation layer of silicon dioxide. In one such implementation a weakly oxidizing plasma containing less than 10 sccm O₂ is employed. In an alternate embodiment, the plasma passivation converts the surface layer of the substrate on the first sidewall into a nitride of the substrate.

In a further embodiment, following the second etch of the substrate, a surface layer of the substrate on the second sidewall of the recess is converted into a passivation layer. The passivation layer formed on the second sidewall has a thickness at least equal to the passivation layer formed on the first sidewall. In one instance the second sidewall is passivated by exposing the recess to ambient air to form a native substrate oxide. In another instance the second sidewall is passivated by exposing the recess to a plasma similar to that used to form the passivation on the first sidewall. In one such embodiment, upon removal of the passivation layers from both the first and second sidewalls, a high aspect ratio feature having a vertical profile is provided. In a specific implementation, after removing the passivation layer from the first and second sidewall, the first and second sidewall are aligned to within 10 Å of each other.

### BRIEF DESCRIPTION OF THE DRAWINGS

Embodiments of the present invention are illustrated by way of example, and not limitation, in the figures of the accompanying drawings in which:

FIG. 1A-1B illustrate a high aspect ratio feature formed by conventional plasma etching.

FIG. 2 illustrates a flow chart of an etching method in accordance with a particular embodiment of the present invention.

FIGS. 3A-3G illustrate cross sectional views of an etching method in accordance with a particular embodiment of the present invention.

FIG. 4 illustrates a schematic of an etch process chamber employed in an embodiment of the present invention.

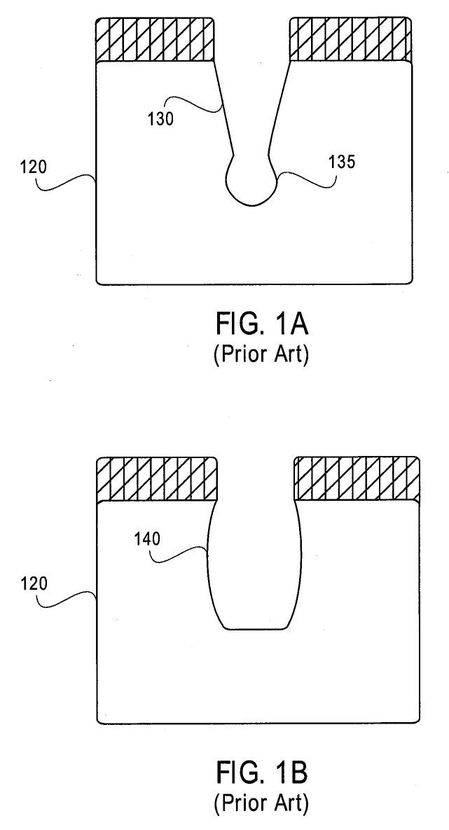

### DETAILED DESCRIPTION

Embodiments of etching and passivating methods are described herein with reference to figures. However, particular embodiments may be practiced without one or more of these specific details, or in combination with other known methods, materials, and apparatuses. In the following description, numerous specific details are set forth, such as specific materials, dimensions and processes parameters etc. to provide a thorough understanding of the present invention. In other instances, well-known semiconductor processes and manufacturing techniques have not been described in particular detail to avoid unnecessarily obscuring the present invention. Reference throughout this specification to “an embodiment” means that a particular feature, structure, material, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, materials, or characteristics may be combined in any suitable manner in one or more embodiments.

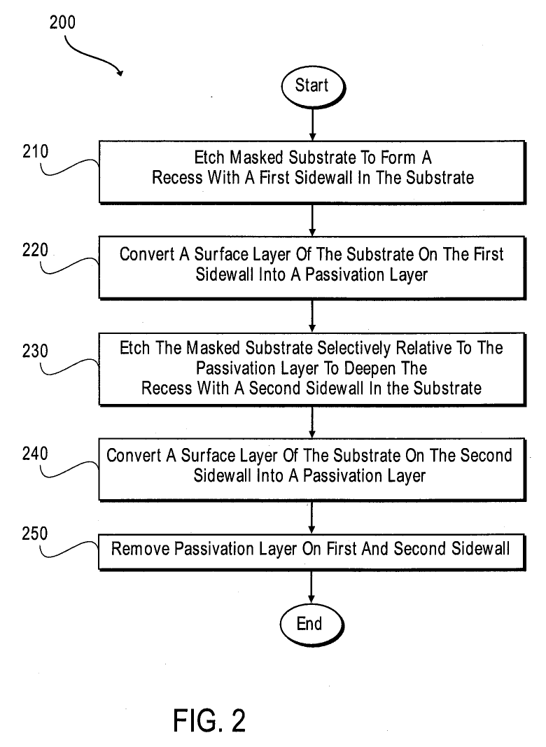

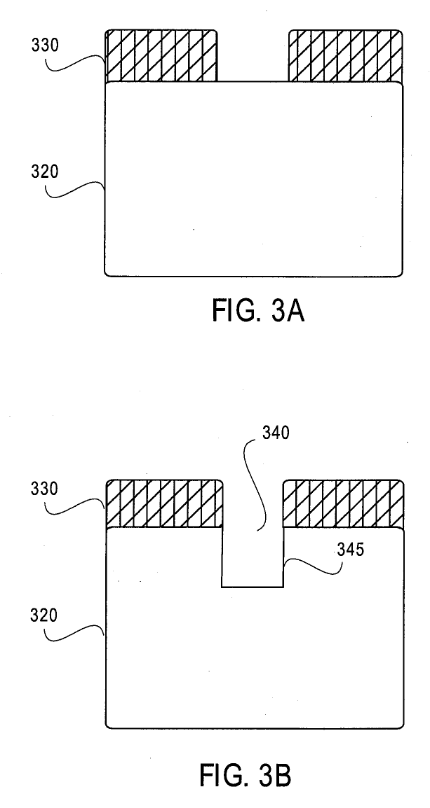

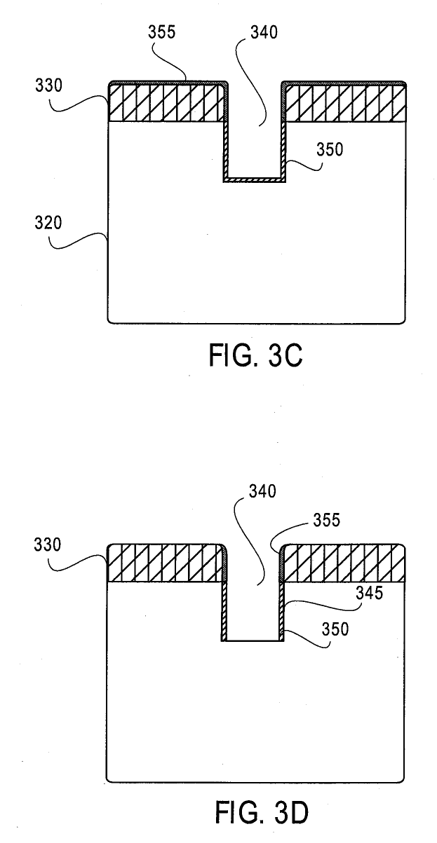

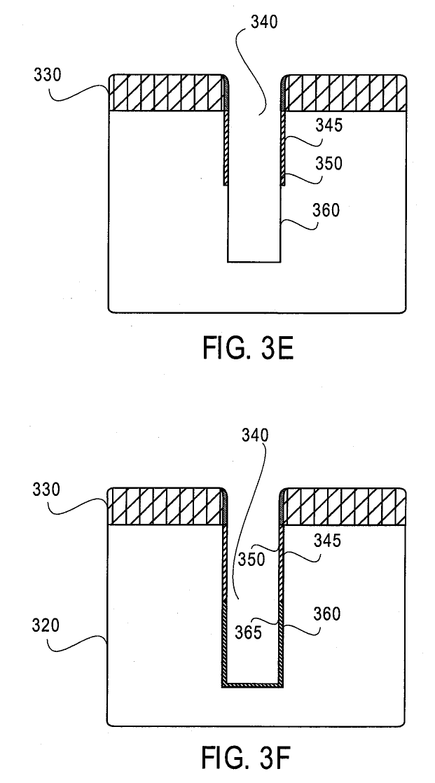

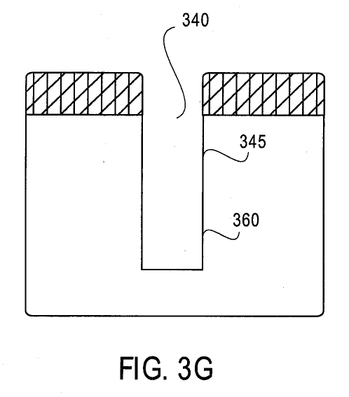

FIG. 2 illustrates a flow chart of etch method 200 for etching a substrate layer with a first etch process followed by a passivating process followed by a second etch process. The distinct passivating process enables the sidewall profile provided by the first etch to be formed and protected independently of the sidewall profile formed by the second etch. In certain embodiments, etch method 200 may be employed to provide a high aspect ratio recess with a vertical sidewall. In other embodiments, etch method 200 may be employed to provide a discontinuous sidewall profiles. In a particular embodiment, processes 210 through 230 are performed within a single plasma etch process chamber as sequential plasma etch processes performed without breaking vacuum. FIGS. 3A-3G illustrate cross-sectional views of a workpiece fabricated with an embodiment of method 200.

Referring to FIG. 3A, the etch method begins with a masked substrate. Generally substrate 320 includes a layer to be etched on a support (not pictured). The layer to be etched may be a material distinct from the support, but it need not be. In one embodiment, the support is a semiconductor wafer, such as, but not limited to monocrystalline silicon, germanium, or a commonly known III-V compound semiconductor material. In another embodiment, the supporting substrate is a glass, such as used in the manufacture of thin film transistors for displays. In still other embodiments, the support is quartz, sapphire or other insulative material. Substrate 320 is distinguished from mask 330 in that mask 330 is a temporary layer employed to transfer a lithographically define pattern into the substrate.

In an exemplary embodiment, substrate 320 includes a conductor layer, such as amorphous silicon or polycrystalline silicon (i.e. polysilicon) or commonly employed metals like aluminum, tantalum, titanium, tungsten, cobalt, nickel and their nitrides. In an alternate embodiment the substrate 320 includes a dielectric layer, such as a nitride layer, a silicon dioxide layer, or a layer of a commonly known low-k material, such as carbon doped oxide. In still another embodiment, substrate 320 includes a semiconductor layer, such as monocrystalline silicon, germanium or other commonly known material. In yet another embodiment, the substrate may further comprise multiple layers of dielectric and/or semiconductor and/or conductor materials, as commonly known in the art.

Generally, substrate 320 is masked with a material resistant to the conditions employed to etch substrate 320. While some applications may employ a commonly known photoresist as mask 330, more typically sacrificial hard mask materials, such as vacuum deposited carbons, metals and dielectrics are employed to provide the necessary etch resistance. In a particular embodiment where substrate 320 is a silicon, such as polysilicon, mask 330 is silicon dioxide formed either thermally or by plasma enhanced chemical vapor deposition (PECVD). In other embodiments where substrate 320 is silicon, mask 330 may also be formed of silicon nitride or oxynitride.

The thickness of mask 330 is dependent on the selectivity of the etch process used to form a recess in substrate 320 and the depth of the recess required. Typically, it is advantageous to minimize the thickness of mask 330. In a particular implementation, a polysilicon substrate 320 is mask by a silicon dioxide mask of less than 500 Å and preferably less than 200 Å. Following deposition of mask 330, commonly known lithography and etch process are employed to pattern mask 330 as shown in FIG. 3A. Masked substrate 320 may then be provided to an etch chamber to proceed with the etch method of the present invention.

The masked substrate is etched at process 210 of etch method 200 of FIG. 2. In one embodiment, the substrate is plasma etched to form a recess having a first sidewall in the substrate. The recess may be for any commonly known fabrication purpose, such as, but not limited to, FinFET definition, DRAM gate recess, shallow trench isolation (STI), dual damascene and conductor etch. In the embodiment shown in FIG. 3B, a plasma etch of process 210 forms an anisotropic recess 340 with first sidewall 345 aligned with mask 330. As shown, the first etch forms a relatively low aspect ratio, below 5:1 and preferably below 4:1. In one such implementation, where substrate 320 is polysilicon, a first plasma etch employs a gas mixture at between 15 and 40 mT containing HBr, Cl₂, SF₆ and N₂, wherein the HBr:Cl₂ ratio is between 1:1 and 5:1, preferably about 2:1, and the SF₆:N₂ ratio is between 0.5:1 and 1:2, preferably about 1:1. The total flow is between 100 standard cubic centimeters per minute (sccm) and 250 sccm with the HBr and Cl₂ flows having a combined flow rate of at least 90 sccm. The plasma is energized with 600 W source power and at least 250 W bias power, preferably 400 W. This particular embodiment, achieves a polysilicon substrate etch rate of approximate 3000 Å/min with a selective to an silicon dioxide mask of over 12:1 with vertical profiles at aspect ratios below about 4:1. In a further implementation, this process is employed to form an anisotropic recess approximately 800 Å deep with a CD of approximately 32 nm into polysilicon substrate 320. In an alternate embodiment not shown, a plasma etch of process 210 comprises commonly known plasma etch process conditions to form an isotropic recess in the substrate with first sidewall undercutting the mask. In still another embodiment not shown, a plasma etch of process 210 comprises commonly known plasma etch process conditions to form an recess in the substrate with first tapered sidewall having a bottom CD smaller than the CD of mask 330.

In a further embodiment, a plasma etch process 210 may include a breakthrough etch prior to etching the substrate. The breakthrough etch typically employs process conditions distinct from those used in the main etch of the substrate and is used to remove material from the surface of the substrate in preparation for etch the substrate with the main etch process. The need for a breakthrough etch is dependent on the surface condition of the masked substrate as provided at the start of etch method 200 and the process conditions of the plasma employed at process 210. In a particular embodiment employing a polysilicon substrate and the exemplary polysilicon etch conditions provided above, process 210 includes a breakthrough comprising a commonly known silicon dioxide plasma etch process condition, such as one providing a fluorocarbon etchant gas at low pressure and energized with low to moderate source powers, to remove any native oxides. In one such embodiment, the breakthrough is performed with tetrafluoromethane (CF₄) and argon (Ar) at a 1:2 to 1:1 ratio, with a chamber pressure of 4 mT energized with 400 W source power and 50 W bias power.

Etch method 200 of FIG. 2 proceeds with converting a surface layer of the substrate on the first sidewall into a passivation layer. In one embodiment, the passivation layer is a native oxide formed on the substrate after etching the substrate at process 210. In another embodiment the passivation layer is formed with a passivation plasma at process 220. In a further embodiment, the passivation layer is formed with a plasma that does not etch the substrate. Formation of the passivation independently from etching the recess enables subsequent etching of the substrate without detriment to the sidewall profiles achieved with the substrate etch in process 210. Once independently passivated, the subsequent etch process conditions need not further provide additional passivation of the sidewall, thereby relaxing the constraints on the subsequent etch of the substrate. In the embodiment shown in FIG. 3C, passivation layer 350 is formed isotropically in recess 340. The passivation plasma may also form a passivation layer on the mask by modifying a region 355 of the mask 330, as further shown in FIG. 3C. In an exemplary embodiment, a silicon dioxide mask 330 altered during the first recess etch of process 210 is oxidized by the passivation plasma. The presence of modified mask region 355 advantageously improves the robustness of the substrate etch processes by reducing mask erosion. The greater mask fidelity enables further tuning of the subsequent substrate etch process for greater uniformity and reduced micro-loading.

Passivation layer 350 is distinguished from a deposited material in that passivation layer 350 is the result of a conversion of a portion substrate 320. Therefore, passivation layer 350 is not merely deposited on the surface of substrate 320, but rather a surface layer of substrate 320 is consumed in an reaction to form passivation layer 350. Because passivation layer 350 is converted from a layer of substrate 320, in an embodiment, the passivation process 220 converts the portion of substrate 320, along the sidewall of the recess and extending under mask 330, into passivation layer 350. Therefore, formation of passivation layer 350 results in an etch bias that is less than the thickness of passivation layer 350. The extent of the etch bias (i.e. CD shrink) is dependent on the relative densities and molecular weights of the substrate atoms and passivation layer atoms. Furthermore, only a thin surface layer of the substrate is to be converted into the passivation layer, limiting the thickness of the passivation layer and thereby avoiding formation of a step between the first sidewall and a second sidewall when recess 340 is subsequently etched a second time. In one implementation, between 3 Å and 15 Å of the surface layer of the substrate on the first sidewall is converted into the passivation layer. In a further implementation, passivation layer 350 is less than 50 Å and in an exemplary embodiment, the passivation layer has a thickness no greater than the thickness of a native oxide of the substrate. Thus, in the particular embodiment where substrate 320 is polysilicon, passivation layer 350 is between 10 Å and 20 Å.

The passivating film may be an oxide, nitride or oxynitride of the substrate. In an embodiment, a passivating substrate oxide may be formed by isotropically oxidizing the recess with a weakly oxidizing plasma. A weakly oxidizing plasma forms a passivation layer that is the proper thickness. In particular embodiments, the weakly oxidizing plasma may comprise a low partial pressure of sulfur dioxide (SO₂) gas or a low partial pressure of oxygen (O₂) gas. In one exemplary implementation, the weakly oxidizing plasma contains less than 10 sccm, and preferably approximately 3 sccm, of oxygen to 100 sccm of helium at a pressure of 10 mT. Because low flows are difficult to maintain accurately with conventional mass flow controllers (MFCs), the oxidizing gas may be first diluted with an inert, such as helium (He). The helium diluted oxidizing gas may then be further combined with additional helium, or another inert, to enable conditions suitable for sustaining a plasma. Thus, in an exemplary embodiment, 10 sccm of a He:O₂ gas mixture may be employed to provide the 3 sccm of oxygen to the etch chamber.

The passivation plasma should be energized with sufficient source power to convert the surface layer of substrate 320 into the preferred 10 Å-20 Å passivation layer. Insufficient source power may result in a discontinuous passivating film having pinholes. In such event, substrate 320 may be attacked by way of the pinholes in passivation layer 350 during a subsequent etch, resulting in an unsatisfactory sidewall. Too much RF power however can result in passivation of substrate 320 at a rate too great for adequate control of the passivation layer thickness. For example, there is a minimum duration required to stabilize a plasma and the passivation layer should not become too thick during this stabilization time. Bias power induces ion bombardment into the substrate with the effect of forming a thicker passivation layer, primarily at the bottom of the recess. As described below, the passivation layer at the bottom of the recess is to be removed eventually to allow further etching of substrate 320. Therefore, in an embodiment, bias power is 0 W to reduce ion bombardment and facilitate an isotropically formed passivation layer of minimum thickness. In one implementation of a weakly oxidizing plasma, a gas comprised of 3 sccm oxygen and 100 sccm helium at 10 mT is energized with a source power of at least 700 W, preferably between 800 W and 1200 W, for a chamber adapted for 300 mm substrates. For the exemplary embodiment with a polysilicon substrate, this specific embodiment provides a silicon dioxide passivation layer with a thickness between 10 Å and 20 Å after an approximately 10 sec plasma exposure.

In an alternate embodiment, the passivation plasma converts the surface layer of the substrate on the first sidewall into an oxynitride of the substrate. In one implementation, a dilute nitrogen oxide, such as nitrous oxide (N₂O), nitric oxide (NO) or nitrogen dioxide (NO₂) is provided to the process chamber. In still another embodiment, a low flow nitrogen source, such as nitrogen (N₂), or ammonia (NH₃) is provided to the etch chamber to convert the surface layer of the substrate on the first sidewall into a nitride of the substrate.

Following the passivation process 220, etch method 200 of FIG. 2 proceeds by etching the masked substrate selectively relative to the passivation layer to deepen the recess with a second sidewall in the substrate. This second etch of the substrate augments the first etch performed in process 210 with the benefit of the passivation formed in process 220. With the passivation formed in process 220, the second etch performed in process 230 may be optimized for the etching the substrate. Thus, the distinct passivation process 200 decouples etch and passivation requirements so it is not necessary to balance between passivating the sidewall and etching the substrate in a single etch process. In one embodiment, the second etch deepens the recess with a continuous profile, for example anisotropic. In one such embodiment, the second etch performed at process 230 increases the aspect ratio of the recess to at least 6:1. In one implementation, more of the substrate is etched in process 210 than process 230. This embodiment may be advantageous because the etch becomes incrementally more demanding with the increasing aspect ratio as the recess is etched. Therefore, the benefit of being able to tune the etch without the additional consideration of sidewall passivation becomes more important as the aspect ratio of the recess becomes greater than about 4:1. However, in an alternate embodiment, the second substrate etch removes approximately the same amount of substrate material as the first substrate etch, for example 800 Å for a total recess depth of approximately 1600 Å, and a CD approximately 32 nm for an AR of 5:1. In one such implementation, a 1600 Å polysilicon layer of the substrate is etched through to facilitate formation of a recessed gate. Furthermore, the passivating and etching plasmas may be performed repeatedly to reach a desired final recess depth and so etching more of the substrate during the first etch at process 210 than the second etch at process 230 of FIG. 2 is not a requirement of all embodiments.

In alternate embodiment, the second etch deepens the recess with a discontinuous profile. For example,.an isotropic etch plasma is employed to laterally expand the recess to form a chamber with a larger CD than that defined by the passivated first sidewall. In still another embodiment where the first substrate etch performed at process 210 provides a tapered sidewall, shrinking CD with increasing depth, the second substrate etch is anisotropic to provide a vertical etch profile below the sloped and passivated sidewall.

Depending on the selectivity of the second substrate etch to the passivation layer, a first breakthrough etch may be employed prior to performing the main etch of process 230. The breakthrough etch should anisotropically etch the passivation layer so the sidewall passivation is retained. In the particular embodiment shown in FIG. 3D, an anisotropic breakthrough removes passivation layer 350 at the bottom of the recess 340 without removing passivation layer 350 from first sidewall 345. The breakthrough may further remove the modified mask region 355 from the top surfaces of mask 330. However, any modified region 355 on the sidewalls of mask 330 will be advantageously retained, improving fidelity of the mask by preventing localized mask erosion mechanisms, such as striations. In one particular implementation, a breakthrough etch substantially the same as the breakthrough etch employed in process 210 of FIG. 2 is employed to break through a silicon dioxide passivation layer 350 of FIG. 3C formed on a silicon comprising substrate 320. In other implementations, a breakthrough etch commonly employed for the particular substrate is utilized. For example, for a substrate of aluminum the breakthrough etch may employ boron trichloride (BCl₃).

In the particular embodiment shown in FIG. 3E, following the breakthrough etch of FIG. 3D, the second substrate etch deepens recess 340 in the substrate. In a particular embodiment, the second substrate etch is anisotropic and forms second sidewall 360 in the substrate aligned with passivation layer 350 on first sidewall 345. Because second sidewall 360 is aligned with the passivation layer 350, it is advantageous for passivation layer 350 to be thin to avoid the formation of a significant step in the recess profile between the first and second sidewall. For example, for a passivation layer 350 between 10 Å and 20 Å, second sidewall 360, aligned to passivation layer 350, is offset from first sidewall 345 by the thickness of the passivation layer 350, or between 10 Å and 20 Å. However, as previously discussed, because passivation layer 350 is formed from the substrate rather than deposited on the substrate, second sidewall is offset from mask 330 only the amount passivation layer 350 extends out from under mask 330, not the full thickness of passivation layer 350. Thus, the second sidewall is offset from mask 330 by an amount based on the relative densities and molecular weights of the substrate atoms and passivation layer atoms. In the particular implementation where a monocrystalline silicon substrate is utilized and a plasma oxidation forms a silicon dioxide passivation layer 350, just under half of passivation layer 350 extends out from under mask 330 based on the difference in density and molecular weight of the silicon substrate and silicon dioxide passivation layer. A similar portion of passivation layer 350 extends out from under mask 330 for polysilicon embodiments. Thus, for certain embodiments with a silicon dioxide passivation layer 350 of between 10 Å and 20 Å, the second sidewall is offset from mask 330 by no more than between about 4 Å and 10 Å.

In one plasma etch embodiment, the process conditions of the second substrate etch in process 230 of FIG. 2 are substantially the same as those of the plasma employed in process 210. As previously described, this exemplary plasma etch is selective to a polysilicon substrate over silicon dioxide by approximately 12:1, therefore the substrate etch is similarly selective to a silicon dioxide passivation layer formed at process 220. This may be advantageous in reducing undesirable profile taper and etch stop. Furthermore, as previously described, the greater mask fidelity provided in embodiments having a modified region 355 on mask 330 enables further tuning of the second etch for greater uniformity and reduced micro-loading. Such tuning may be achieved with modification of chamber pressure and gas flow rates, as well as other means generally known in the art. In another plasma etch embodiment, the substrate is etched at process 230 with commonly known isotropic etchants, such as NF₃ and/or SF₆ for a silicon substrate.

In a further embodiment, at process 240 etch method 200 of FIG. 2, a surface layer of the substrate on the second sidewall of the recess is then converted into a passivation layer. In one embodiment, as shown in FIG. 3F, passivation layer 365 formed on second sidewall 360 has a thickness at least equal to passivation layer 350 formed on first sidewall 345. With passivation layer 350 approximately the same thickness of the passivation layer 365, the first sidewall 345 and second sidewall 360 become closely aligned to provide a continuous sidewall of high aspect ratio recess 340. In one implementation, the second sidewall is passivated by exposing the recess to ambient air to form a native substrate oxide. This may be accomplished simply upon removing the substrate from the vacuum of the etch chamber used to perform certain of the plasma etch and passivation processes described herein. This embodiment is advantageous because no plasma processing time is required and the self-limiting nature of native oxide ensures repeatability. Furthermore, the thickness of passivation layer 350 is not further increased during the formation of a native oxide passivation layer 365. Thus, in the particular embodiment where substrate 320 is monocrystalline silicon or polysilicon, between 10 Å and 20 Å of native silicon dioxide is formed in the recess along second sidewall 360. In another instance, the second sidewall 360 is passivated by exposing the recess to another plasma, such as that used to form passivation layer 350 on the first sidewall. This embodiment is useful for iteratively etching and passivating a recess any number of times to achieve a desired depth or profile with successive etching and passivating processes.

At process 250 of etch method 200 of FIG. 2, the passivation layer on the first and second sidewall is removed with commonly known techniques dependent on the composition of the passivation layers. As shown in the embodiment of FIG. 3G, removal of passivation layers 350 and 365 provides a vertical profile because each sidewall portion remains vertical throughout the etch process. In embodiments where passivation layer 365 has a thickness at least equal to passivation layer 350, removal of the passivation layers leave first sidewall 345 and second sidewall 360 closely aligned with each other. In a specific implementation, after removing the passivation layer from the first sidewall 345 and second sidewall 360, the two sidewalls of the high aspect ratio recess are aligned to within 10 Å of each other. In one particular embodiment, with a passivation layer 350 of silicon dioxide formed by plasma oxidation of substrate 320 and a passivation layer 350 of native silicon dioxide formed upon exposure of substrate 320 to ambient conditions, both passivation layer 350 and passivation layer 365 are removed with a single wet chemical etch comprising hydrofluoric acid (HF). As further shown in FIG. 3G, mask region 355 is also removed along with passivation layers 350 and 365. In other embodiments, passivation layers 350 and 365 may be removed when mask 330 is subsequently removed (not shown). In an alternate embodiment, with a passivation layer 350 of silicon nitride formed by plasma nitridation of substrate 320 and a passivation layer 350 of native silicon dioxide formed upon exposure of substrate 320 to ambient conditions, passivation layer 350 is removed with a first chemical etch, such as one comprising phosphoric acid (H₃PO₄), and passivation layer 365 is removed with a second chemical etch, such as one comprising hydrofluoric acid (HF). In still another embodiment, passivation layers 350 and 365 are removed under vacuum, for example with a reducing agent, with or without plasma enhancement, as an in-situ process of a film deposition in recess 340. Thus, as described the etch method 200 of FIG. 2 ends, providing in particular embodiments, high aspect ratios (e.g. greater than at least 4:1 and preferably above 5:1) with vertical profiles.

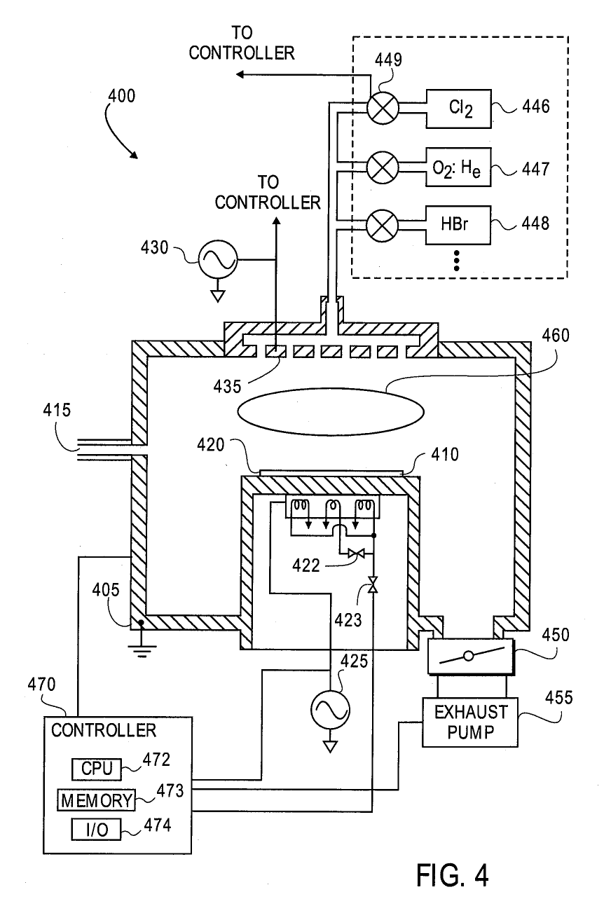

In an embodiment, certain processes of etch method 200 are performed in an etch process chamber, such as the AdvantEdge G3, manufactured by and commercially available from Applied Materials of CA, USA. It is to be understood that other etch chambers can also be used for practicing embodiments of the present invention. A cross-sectional view of an exemplary etch chamber 400 is shown in FIG. 4. Etch chamber 400 includes a process chamber 405. A substrate 410 is loaded through an opening 415 and placed on a temperature controlled chuck 420. Chuck 420 may be temperature controlled with a dual-zone helium cooling system, wherein valve 422 regulates backside helium pressure independently from valve 423 to improve wafer temperature tuning to offer both a greater range of center-to-edge thermal gradients and better temperature uniformity.

Process gases, such as Cl₂, O₂:He, and HBr, are provide to process chamber 405 in an embodiment of the etch method previously described. The process gases are supplied from sources 446, 447 and 448, respectively, contained within a gas panel 441. The process gases are supplied from the source through respective mass flow controllers 449 to the interior of the process chamber 405. Other gases, such as SF₆, N₂, nitrogen oxides, SO₂, and O₂ may further be provided (not shown). Process chamber 405 is evacuated via an exhaust valve 450 connected to a high capacity vacuum pump stack 455.

Coil 435 and chuck 420 form a pair of electrodes. When radio frequency (RF) power is applied, process gas within process chamber 405 is ignited by the fields formed between the pair of electrodes to form plasma 460. Generally, an electric field is produced by coupling chuck 420 to a source 425 of single or double frequency RF. Alternatively, RF source 430 may be coupled to coil 435 or both RF sources 430 and 425 may be employed. Coil 435 may further be a tunable dual-coil source.

In an embodiment of the present invention, etch chamber 400 is computer controlled by controller 470 to control the RF power, gas flows, pressure, chuck temperature, as well as other process parameters. Controller 470 may be one of any form of general-purpose data processing system that can be used in an industrial setting for controlling the various subprocessors and subcontrollers. Generally, controller 470 includes a central processing unit (CPU) 472 in communication with memory 473 and input/output (I/O) circuitry 474, among other common components. Software commands executed by CPU 472, cause etch chamber 400 to plasma etch recess in a substrate a first time, plasma passivate the recess sidewalls by converting a layer of the substrate into a passivation layer, and then plasma etch the recess in the substrate a second time. In one such embodiment, the second etch increases the aspect ratio of the recess while maintaining vertical sidewall profiles. In another embodiment, software commands executed by CPU 472, cause etch chamber 400 to etch approximately 800 Å of polysilicon, form approximately 10 Å-20 Å of silicon dioxide with a weakly oxidizing plasma comprising a gas mixture of 3:100 O₂:He, and then etch another approximately 800 Å of polysilicon.

Portions of the present invention may be provided as a computer program product, which may include a computer-readable medium having stored thereon instructions, which when executed by a computer (or other electronic devices), cause a process chamber to plasma etch recess in a substrate a first time, plasma passivate the recess sidewalls by converting a layer of the substrate into a passivation layer, and then plasma etch the recess in the substrate a second time. In one such embodiment, the second etch increases the aspect ratio of the recess while maintaining vertical sidewall profiles. In other embodiments, a computer-readable medium has stored thereon instructions, which when executed by a computer (or other electronic devices), cause a process chamber to etch approximately 800 Å of polysilicon, form approximately 10 Å-20 Å of silicon dioxide with a weakly oxidizing plasma comprising a gas mixture of 3:100 O2:He, and then etch another approximately 800 Å of polysilicon. The computer-readable medium may include, but is not limited to, floppy diskettes, optical disks, CD-ROMs (compact disk read-only memory), and magneto-optical disks, ROMs (read-only memory), RAMs (random access memory), EPROMs (erasable programmable read-only memory), EEPROMs (electrically-erasable programmable read-only memory), magnet or optical cards, flash memory, or other commonly known type computer-readable medium suitable for storing electronic instructions. Moreover, the present invention may also be downloaded as a computer program product, wherein the program may be transferred from a remote computer to a requesting computer over a wire.

Although the present invention has been described in language specific to structural features and/or methodological acts, it is to be understood that the invention defined in the appended claims is not necessarily limited to the specific features or acts described. The specific features and acts disclosed are to be understood as particularly graceful implementations of the claimed invention in an effort to illustrate rather than limit the present invention.

What is claimed is:

1. An etch method comprising:
etching a masked substrate with an etching plasma to form a recess with a first sidewall in the substrate;
converting a surface layer of the substrate on the first sidewall into a passivation layer with a passivating plasma; and
etching the masked substrate selectively relative to the passivation layer with an etching plasma to deepen the recess with a second sidewall in the substrate.

2. The method of claim 1, wherein the passivation layer has a thickness approximately equal to the thickness of a native oxide of the substrate.

3. The method of claim 1, wherein the passivation plasma converts the surface layer of the substrate on the first sidewall into an oxide of the substrate.

4. The method of claim 3, wherein the substrate comprises polycrystalline silicon and the passivation layer comprises silicon dioxide.

5. The method of claim 1, wherein the passivation plasma converts the surface layer of the substrate on the first sidewall into a nitride of the substrate.

6. The method of claim 1, further comprising converting a surface layer of the substrate on the second sidewall into a passivation layer.

7. The method of claim 6, wherein converting the surface layer of the substrate on the second sidewall to a passivation layer further comprises exposing the recess to ambient air to form a native substrate oxide.

8. The method of claim 6, wherein the passivation layer formed on the second sidewall has a thickness at least equal to the passivation layer formed on the first sidewall.

9. The method of claim 6, wherein converting the surface layer of the substrate on the second sidewall into a passivation layer further comprises exposing the recess to a plasma.

10. The method of claim 6, wherein, after removing the passivation layer from the first sidewall and the passivation layer from the second sidewall, the first and second sidewalls are aligned to within 10 Å of each other to form a recess with a substantially vertical profile.

11. The method of claim 1, wherein the surface layer of the substrate on the first sidewall is converted into a passivation layer less than 50 Å thick.

12. The method of claim 11, wherein between 3 Å and 15 Å of the surface layer of the substrate on the first sidewall is converted into the passivation layer.

13. A method of plasma etching a feature comprising:
providing a masked substrate in a chamber;
anisotropically etching the masked substrate with a first plasma to form a recess having a first sidewall in the substrate aligned with the mask;
isotropically oxidizing the recess with a second plasma to form a passivation layer on the first sidewall;
anisotropically etching the passivation layer with a third plasma to break through the passivation layer at the bottom of the recess;
anisotropically etching the masked substrate with a fourth plasma to deepen the recess with a second sidewall in the substrate aligned with the passivation layer on the first sidewall; and
removing the substrate from the chamber.

14. The method of claim 13, wherein the process conditions of the first and third plasma are substantially the same.

15. The method of claim 13, wherein the first plasma etches more of the substrate than the third plasma.

16. The method of claim 13, wherein the second plasma is substantially free of halogens and fluorocarbons and comprises a gas selected from the group consisting of: SO₂, O₂, He, nitrogen oxides, N₂ and NH₃.

17. The method of claim 16, wherein the second plasma comprises less than 10 sccm O₂,

18. The method of claim 16, wherein the second plasma is energized with at least 700 W source power in a process chamber adapted for 300 mm substrates.

19. A computer-readable medium having stored thereon a set of machine-executable instructions that, when executed by a data-processing system, cause a system to perform a method comprising:
etching a masked substrate with a first plasma to form a recess with a first sidewall in the substrate;
converting a surface layer of the substrate on the first sidewall into a passivation layer with a second plasma; and
etching the masked substrate selectively relative to the passivation layer with a third plasma to deepen the recess with a second sidewall in the substrate.

20. The computer-readable medium of claim 19, comprising a set of machine-executable instructions that, when executed by a data-processing system, cause a system to perform a method wherein the passivation layer is formed to a thickness approximately equal to the thickness of a native oxide of the substrate.
